(19) United States
(12) Patent Application Publication
(10) Pub. No.: US 2025/0298202 A1
(43) Pub. Date: Sep. 25, 2025

(54) TECHNOLOGIES FOR BRIDGE DIES FOR OPTICAL INTERCONNECTS

(71) Applicant: Intel Corporation, Santa Clara, CA (US)

(72) Inventors: Tolga Acikalin, San Jose, CA (US); Ankur Agrawal, Chandler, AZ (US); Gang Duan, Chandler, AZ (US); Benjamin T. Duong, Phoenix, AZ (US); Sandeep Gaan, Chandler, AZ (US); James E. Jaussi, El Dorado Hills, CA (US); Mozhgan Mansuri, Portland, OR (US); Srinivas Venkata Ramanuja Pietambaram, Chandler, AZ (US)

(73) Assignee: Intel Corporation, Santa Clara, CA (US)

(21) Appl. No.: 18/613,549

(22) Filed: Mar. 22, 2024

(51) Int. Cl. G02B 6/42

(52) U.S. Cl. CPC G02B 6/4257; G02B 6/4246; G02B 6/4283

(57) ABSTRACT

Technologies for bridge dies for optical interconnects are disclosed. In an illustrative embodiment, build-up layers are adjacent a substrate, and a bridge die and a photonic integrated circuit (PIC) die are each mounted on the substrate. An xPU die is mounted on the build-up layers and the bridge die, and another electronic integrated circuit (EIC) die is mounted on the bridge die and the PIC die. The bridge die can both transfer electronic signals between the XPU and the EIC die as well as provide power signals from the substrate through one or more through-silicon vias defined in the bridge die. The power signals can be provided to the PIC die, which allows for a shorter path for a power signal compared to passing the power signal through the build-up layers. The shorter path for the power signal can improve power delivery integrity and reduce parasitic power delivery drops.

### BACKGROUND

Photonic integrated circuit (PIC) dies can be used for several applications, such as communications. PIC dies can offer high-speed, compact communication. However, PIC dies may be fabricated on separate dies from electronic integrated circuit (EIC) dies on the same package. As a result, total trace length for power signals may be relatively long, due to passing through build-up layers and extending through one or more EIC dies before reaching the PIC die. Such long trace lengths may result in worse power delivery integrity and parasitic power delivery drops.

### BRIEF DESCRIPTION OF THE DRAWINGS

FIG. 1 is an isometric view of a system including an integrated circuit package with a substrate, electrical integrated circuit (EIC) dies, a bridge die, and a photonic integrated circuit (PIC) die.

FIG. 2 is a top-down view of the system of FIG. 1.

FIG. 3 is a cross-sectional view of one embodiment of the system of FIG. 1.

FIG. 4 is a cross-sectional view of one embodiment of a system including an EIC die, a bridge die, and a PIC die.

FIG. 5 is a cross-sectional view of one embodiment of a system including an EIC die, a bridge die, and a PIC die.

FIG. 6 is a cross-sectional view of one embodiment of a system including an EIC die, a bridge die, and a PIC die.

FIG. 7 is a cross-sectional view of one embodiment of a system including an EIC die, a bridge die, and a PIC die.

FIG. 8 is a top-down view of one embodiment of a system including an EIC die, a bridge die, and a PIC die.

FIG. 9 is a cross-sectional view of one embodiment of the system of FIG. 7.

FIG. 10 is a top-down view of one embodiment of a system including an EIC die, a bridge die, and a PIC die.

FIG. 11 is a top-down view of one embodiment of a system including several EIC dies and a bridge die.

FIG. 12 is a cross-sectional view of one embodiment of the system of FIG. 10.

FIG. 13 is a cross-sectional view of one embodiment of a system including an EIC die, a bridge die, and a micro-LED dic.

FIG. 14 is a top view of a wafer and dies that may be included in a microelectronic assembly, in accordance with any of the embodiments disclosed herein.

FIG. 15 is a cross-sectional side view of an integrated circuit device that may be included in a microelectronic assembly, in accordance with any of the embodiments disclosed herein.

FIGS. 16A-16D are perspective views of example planar, gate-all-around, and stacked gate-all-around transistors.

FIG. 17 is a cross-sectional side view of an integrated circuit device assembly that may include a microelectronic assembly, in accordance with any of the embodiments disclosed herein.

FIG. 18 is a block diagram of an example electrical device that may include a microelectronic assembly, in accordance with any of the embodiments disclosed herein.

### DETAILED DESCRIPTION

In various embodiments disclosed herein, a system includes an electronic integrated circuit (EIC) die, a bridge die, and a photonic integrated circuit (PIC), such as a PIC die. In an illustrative embodiment, the bridge die includes through-silicon vias that provide power signals to the photonic integrated circuit. The bridge die can provide a more direct path for a power signal compared to, e.g., going through build-up layers and an EIC die. As a result, power delivery integrity improves, and parasitic power delivery drops.

As used herein, the phrase “communicatively coupled” refers to the ability of a component to send a signal to or receive a signal from another component. The signal can be any type of signal, such as an input signal, an output signal, or a power signal. A component can send or receive a signal to another component to which it is communicatively coupled via a wired or wireless communication medium (e.g., conductive traces, conductive contacts, air). Examples of components that are communicatively coupled include integrated circuit dies located in the same package that communicate via an embedded bridge in a package substrate and an integrated circuit component attached to a printed circuit board that send signals to or receives signals from other integrated circuit components or electronic devices attached to the printed circuit board.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. “Connected” may indicate elements are in direct physical or electrical contact, and “coupled” may indicate elements co-operate or interact, but they may or may not be in direct physical or electrical contact. Furthermore, the terms “comprising,” “including,” “having,” and the like, as used with respect to embodiments of the present disclosure, are synonymous. Terms modified by the word “substantially” include arrangements, orientations, spacings, or positions that vary slightly from the meaning of the unmodified term. For example, the central axis of a magnetic plug that is substantially coaxially aligned with a through hole may be misaligned from a central axis of the through hole by several degrees. In another example, a substrate assembly feature, such as a through width, that is described as having substantially a listed dimension can vary within a few percent of the listed dimension.

It will be understood that in the examples shown and described further below, the figures may not be drawn to scale and may not include all possible layers and/or circuit components. In addition, it will be understood that although certain figures illustrate transistor designs with source/drain regions, electrodes, etc. having orthogonal (e.g., perpendicular) boundaries, embodiments herein may implement such boundaries in a substantially orthogonal manner (e.g., within +/−5 or 10 degrees of orthogonality) due to fabrication methods used to create such devices or for other reasons.

Reference is now made to the drawings, which are not necessarily drawn to scale, wherein similar or same numbers may be used to designate the same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

In the following description, for purposes of explanation, numerous specific details are set forth in order to provide a thorough understanding thereof. It may be evident, however, that the novel embodiments can be practiced without these specific details. In other instances, well-known structures and devices are shown in block diagram form in order to facilitate a description thereof. The intention is to cover all modifications, equivalents, and alternatives within the scope of the claims.

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

As used herein, the term “adjacent” refers to layers or components that are in physical contact with each other. That is, there is no layer or component between the stated adjacent layers or components. For example, a layer X that is adjacent to a layer Y refers to a layer that is in physical contact with layer Y.

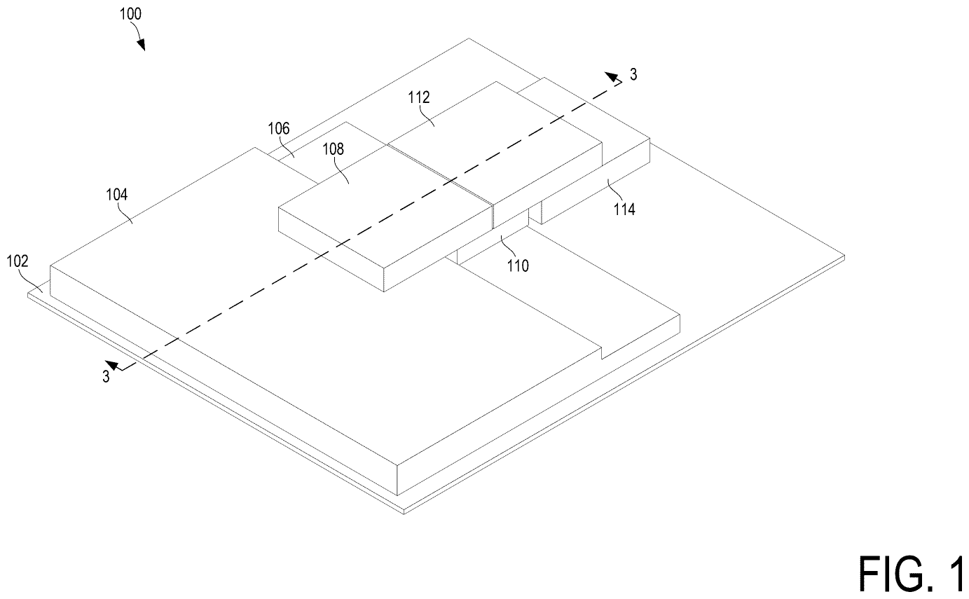

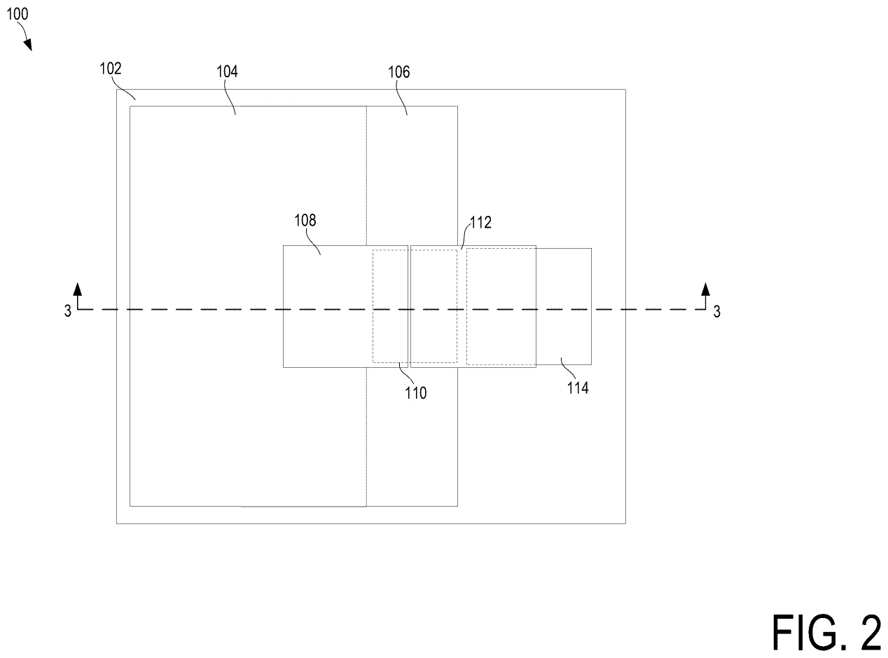

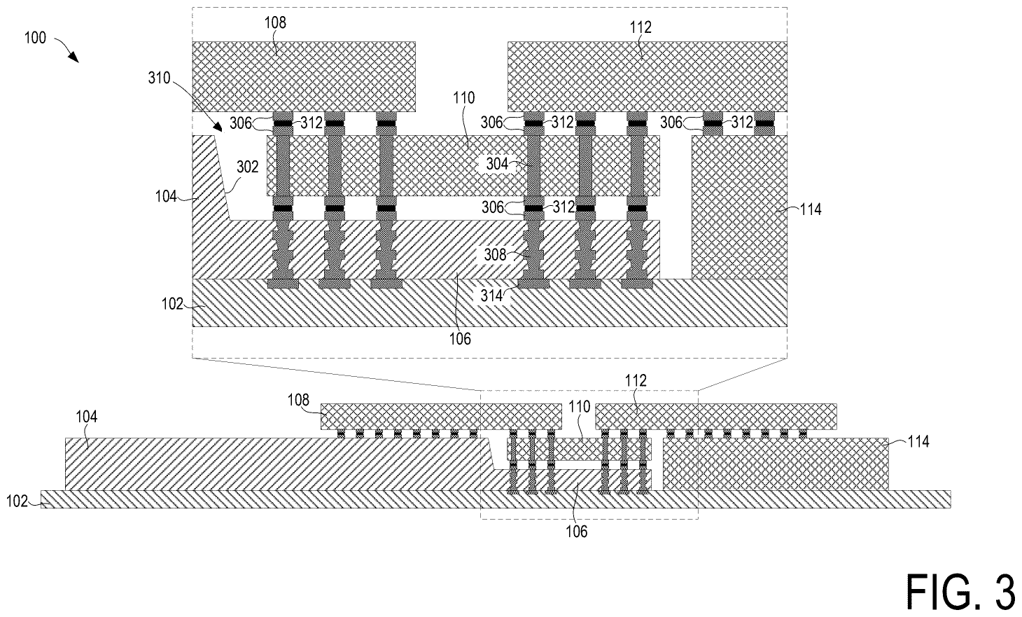

Referring now to FIGS. 1-3, in one embodiment, an integrated circuit package 100 includes a substrate 102, one or more build-up layers 104, an EIC die 108 mounted on the build-up layers 104, a PIC die 114 mounted on the substrate 102, an EIC die 112 mounted on the PIC die 114, and a bridge die 110 that is mounted on a shelf 106 defined in the build-up layers 104. The bridge die 110 may be connected to the substrate 102, the EIC die 108, and the EIC die 112. FIG. 1 shows a perspective view of the integrated circuit package 100, FIG. 2 shows a top-down view of the integrated circuit package 100, and FIG. 3 shows a cross-sectional view of one embodiment of the integrated circuit package 100.

In an illustrative embodiment, traces 314 are defined in the substrate 102. The traces 314 carry power signals for the PIC die 114 and, in some embodiments, for the EIC die 112 and/or the EIC die 108 as well. In the illustrative embodiment, a cavity 310 is defined in the build-up layers 104, forming a shelf 106 on which the bridge die 110 is mounted. A stack 308 of traces and vias defined in the build-up layers 104 connect the traces 314 to pads 306 on the build-up layers 104. The pads 306 on the build-up layers 104 are connected to pads 306 on the bridge die 110. The pads 306 of the build-up layers 104 and the bridge die 110 may be connected by, e.g., a solder bump 312, a hybrid bond, and/or the like. The pads 306 on the bottom of the bridge die 110 are connected to pads 306 on the top of the bridge die 110 by through-silicon vias 304. The pads 306 on top of the bridge die 110 are connected to pads 306 on the bottom of the EIC die 112, such as by solder bumps 312, hybrid bonds, etc. Traces in the EIC die 112 connect the pads 306 above the bridge die 110 to pads 306 above the PIC die 114. The pads 306 of the EIC die 112 above the PIC die 114 are connected to pads 306 on the PIC die 114, such as through solder bumps 312, hybrid bonds, etc.

In this manner, power can be delivered from the substrate 102, through the build-up layers 104, through the bridge die 110, and through the EIC die 112 to the PIC die 114. It should be appreciated that alternate paths for power delivery may require longer traces lengths in, e.g., the EIC die 108. In some embodiments, the edge 302 of the build-up layers 104 may be slightly angled and/or power vias and/or traces may be restricted from being within, e.g., a lateral distance of 100-500 micrometers from the PIC die 112. In contrast, the through-silicon vias 304 in the bridge die 110 can be, e.g., a lateral distance of 10-80 micrometers from the edge of the PIC die 114, leading to a shorter path length for a power signal, better power delivery integrity, and less parasitic loss.

The illustrative substrate 102 is glass, such as silicon oxide glass. In other embodiments, the substrate 102 may be made of any suitable material that may be crystalline, non-crystalline, amorphous, etc., such as fused silicon, borosilicate, sapphire, yttrium aluminum garnet, etc. The glass substrate 102 may be, e.g., aluminosilicate glass, borosilicate glass, alumino-borosilicate glass, silica, fused silica. The glass substrate 102 may include one or more additives, such as Al2O3, B2O3, MgO, CaO, SrO, BaO, SnO2, Na2O, K2O, SrO, P2O3, ZrO2, Li2O, Ti, and Zn. The glass substrate 102 may comprise silicon and oxygen, as well as any one or more of aluminum, boron, magnesium, calcium, barium, tin, sodium, potassium, strontium, phosphorus, zirconium, lithium, titanium, and zinc. The glass substrate 102 may include at least 20-40 percent silicon by weight, at least 20-40 percent oxygen by weight, and at least 5 percent aluminum by weight. For example, some embodiments of the glass substrate 102 may include, e.g., at least 20-23 percent silicon and at least 20-26 percent oxygen by weight.

In other embodiments, the substrate 102 may be any suitable material, such as a ceramic substrate or an organic substrate. In some embodiments, the substrate 102 may be embodied as a printed circuit board made from ceramic, and/or organic-based materials with fiberglass and resin, such as FR-4. The substrate 102 may have any suitable length or width, such as 10-500 millimeters. The substrate 102 may have any suitable thickness, such as 0.2-5 millimeters. The substrate 102 may support additional components besides the build-up layers 104, EIC dies 108, 112, bridge die 110, and PIC die 114, such as additional photonic or electronic integrated circuit components, a processor unit, a memory device, an accelerator device, etc.

The cavity 310 and shelf 106 may be formed in any suitable manner. In an illustrative embodiment, the cavity 310 is formed by removing material from the build-up layers 104, such as by using a mechanical drill, a laser drill, a wet etch, a dry etch, etc. The height of the build-up layers 104 may be any suitable value, such as 5-500 micrometers. The height of the shelf 106 may be any suitable value, such as 3-300 micrometers. It should be appreciated that the smaller height of the shelf 106 relative to the rest of the build-up layers 104 can allow for the stack 308 of traces and vias to be closer to the edge of the PIC die 114 than in other places in the build-up layers 104. The shelf 106 allows for the bridge die 110 to be positioned at different heights and/or for bridge dies 110 or different thicknesses to be used.

The PIC die 114 may be made of any suitable material, such as silicon. In the illustrative embodiment, waveguides are defined in the PIC die 114. The waveguides may be silicon waveguides embedded in silicon oxide cladding. The PIC die 114 may include any suitable number of waveguides, such as 1-1,024. In an illustrative embodiment, the waveguides in the PIC die 114 are edge-coupled waveguides. In other embodiments, the waveguides may be vertically coupled out of the PIC die 114. In some embodiments, the PIC die 114 may be embodied as or include, e.g., indium phosphide, gallium arsenide, lithium niobate, silicon nitride, chalcogenide, and/or the like.

The PIC die 114 is configured to generate, detect, and/or manipulate light. The PIC die 114 may include active or passive optical elements such as splitters, couplers, filters, optical amplifiers, lasers, photodetectors, modulators, routers, etc. The PIC die 114 may operate at any suitable wavelength, such as 400-2,000 nanometers. In the illustrative embodiment, the PIC die 114 operates around, e.g., 1,200-1,400 nanometers.

The EIC die 108 and/or 112 may include any suitable electronic integrated circuit component, such as resistors, capacitors, inductors, transistors, etc. The EIC die 108 and/or 112 may include any suitable analog and/or digital circuitry, such as a processor, a memory, an application-specific integrated circuit (ASIC), a field-programmable gate array (FPGA), etc. In an illustrative embodiment, the EIC die 108 may be embodied as an xPU, such as a central processing unit or a graphics processing unit, and the EIC die 112 may be embodied as or otherwise include circuitry to drive components on the PIC die 114, such as lasers and modulators, and/or circuitry to receive signals from components on the PIC die 114, such as photodetectors. The EIC die 112 may use the PIC die 114 to communicate using optical signals with other dies in the same package 100, other integrated circuit packages, other compute devices, etc. In some embodiments, the integrated circuit package 100 may be embodied as a router, a switch, a network interface controller, and/or the like. In such embodiments, the EIC die 108 and/or 112 may include network interface controller circuitry to process, parse, route, etc., network packets sent and received by the integrated circuit package 100.

The EIC die 108 is mounted on the build-up layers 104. The EIC die 108 is connected to the build-up layers 104 and the substrate 102 through pads 306 and/or solder bumps 312. The pads 306 and/or solder bumps 312 may be used to transmit and receive signals between the EIC die 108 and the substrate 102, provide power to the EIC die 108, etc. The substrate 102 may provide various electrical connections. For example, the substrate 102 may include a redistribution layer on the bottom of the substrate 102 and/or may include a redistribution layer on the top of the substrate 102, which may be embodied as the build-up layers 104.

The bridge die 110 provides interconnect circuitry for connections between the EIC dies 108, 112 and/or the substrate 102. The bridge die 110 may be embodied as, e.g., an embedded multi-die interconnect bridge (EMIB) or an omni-directional interconnect (ODI). The bridge die 110 may carry power signals and/or data signals to, from, or between any suitable combination of the EIC dies 108, 112 and the substrate 102. For example, power may be provided from the substrate 102, through the bridge die 110, through the EIC die 112, to the PIC die 114, and data signals may be sent between the EIC die 108 and the PIC die 114 through the bridge die 110 and the EIC die 112. The bridge die 110 may include any suitable number of power and/or data signal pads 306 connected to each of the EIC die 108, EIC die 112, build-up layers 104, or other component, such as 1-1,024 pads 306.

In some embodiments, the bridge die 110 may include thermal plugs or thermal vias to assist in heat removal. In some embodiments, some or all of the through-silicon vias 304 may operate as thermal vias as well as conductive power pathway vias.

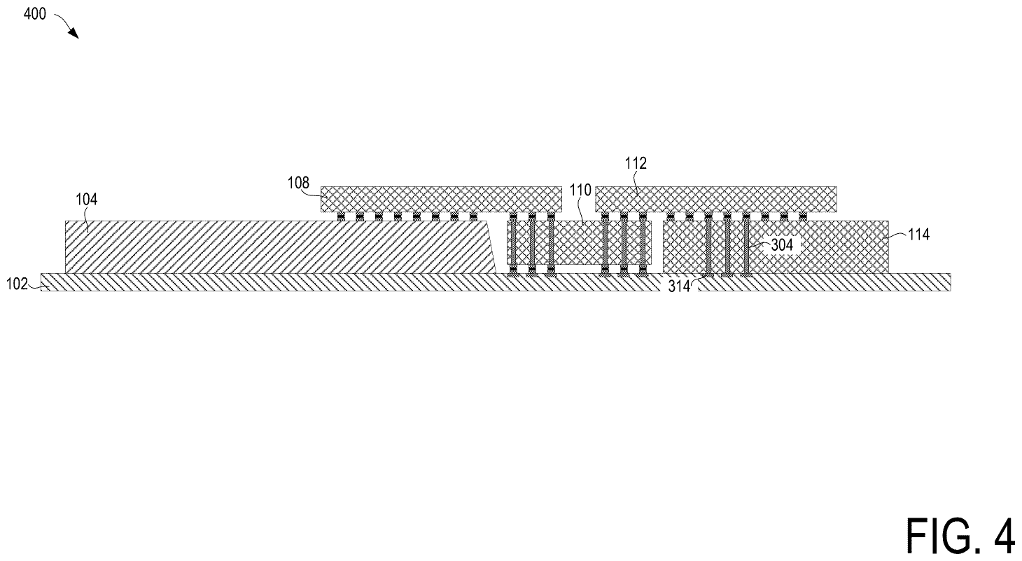

Referring now to FIG. 4, in one embodiment, an integrated circuit package 400 includes a substrate 102, one or more build-up layers 104, an EIC die 108 mounted on the build-up layers 104, a PIC die 114 mounted on the substrate 102, an EIC die 112 mounted on the PIC die 114, and a bridge die 110 mounted on the substrate 102. The various components of the integrated circuit package 400 may be similar to or the same as the integrated circuit package 100 or other integrated circuit packages described herein, a detailed description of which will not be repeated in the interest of clarity. In the integrated circuit package 400, the bridge die 110 is mounted directly on the substrate 102. Mounting the bridge die 110 directly on the substrate 102 may provide certain advantages in some embodiments, such as a shorter total trace length for a power signal to the PIC dic 114.

In some embodiments, as shown in FIG. 4, the PIC die 114 may include through-silicon vias 304 (or through-die vias 304, if the PIC die 114 is not a silicon substrate). The through-silicon vias 304 may provide power or data signals from the substrate 102, through the PIC die 114, towards a top surface of the PIC die 114, where components such as lasers, modulators, amplifiers, etc., may be located. The connections provided by the vias 304 may be in place of or in addition to the vias 304 in the bridge die 110.

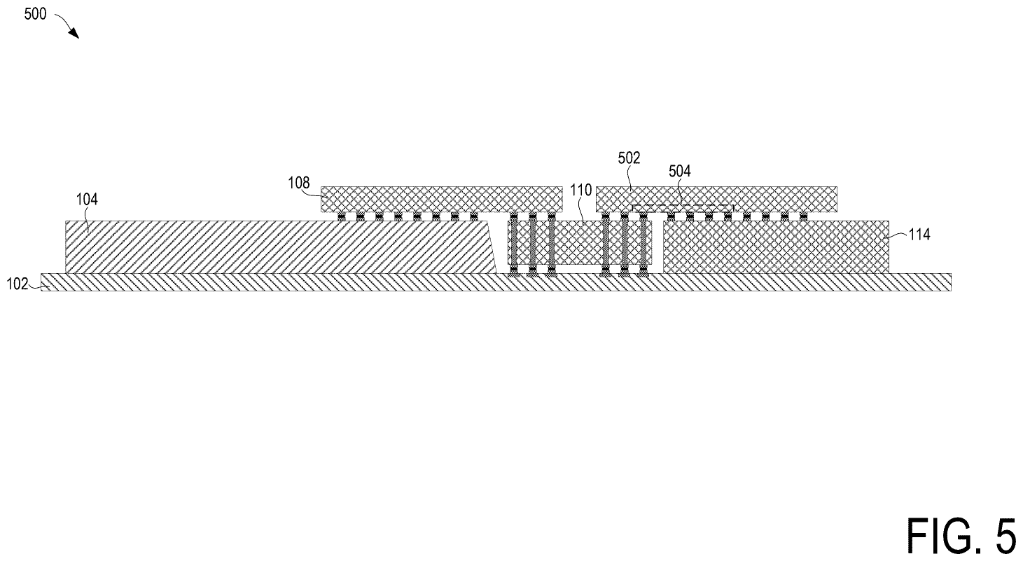

Referring now to FIG. 5, in one embodiment, an integrated circuit package 500 includes a substrate 102, one or more build-up layers 104, an EIC die 108 mounted on the build-up layers 104, a PIC die 114 mounted on the substrate 102, an input/output (I/O) die 502 mounted on the PIC die 114 with a PIC driver block 504, and a bridge die 110 mounted on the substrate 102. The various components of the integrated circuit package 500 may be similar to or the same as the integrated circuit package 100 or other integrated circuit packages described herein, a detailed description of which will not be repeated in the interest of clarity. The I/O die 502 may include circuitry for performing I/O, such as network interface controller (NIC) circuitry. The I/O die 502 includes PIC driver block 504 to interface with the PIC die 114.

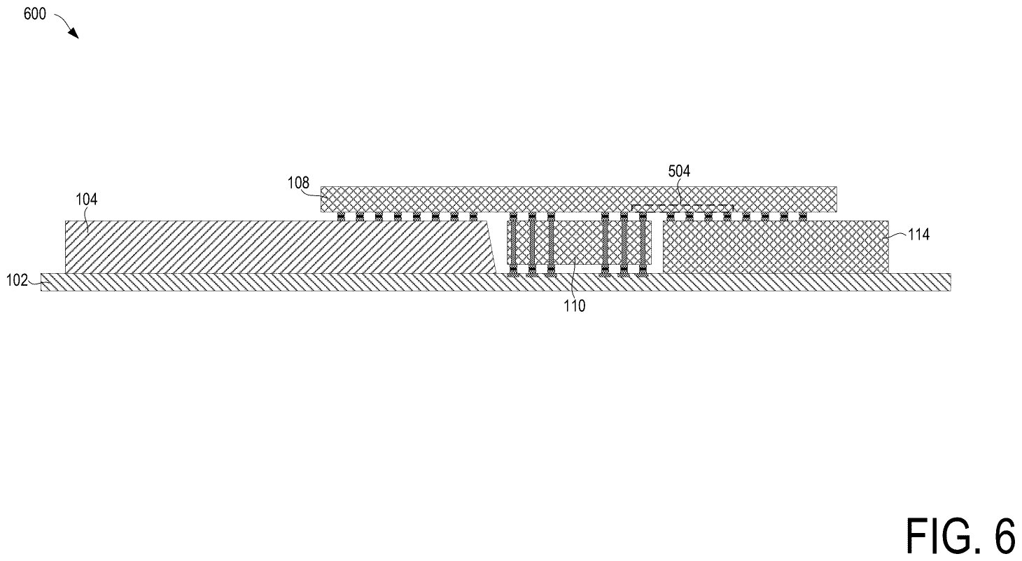

Referring now to FIG. 6, in one embodiment, an integrated circuit package 600 includes a substrate 102, a PIC die 114 mounted on the substrate 102, one or more build-up layers 104, a bridge die 110 mounted on the substrate 102, and an EIC die 108 mounted on the build-up layers 104, the bridge die 110, and the PIC die 114. The various components of the integrated circuit package 600 may be similar to or the same as the integrated circuit package 100 or other integrated circuit packages described herein, a detailed description of which will not be repeated in the interest of clarity. The EIC die 108, which may be an xPU, includes PIC driver circuitry 504 to interface with the PIC die 114. As for the integrated circuit package, power for the PIC dic 114 may be provided by the substrate 102, through the bridge die 110, and through the EIC 108.

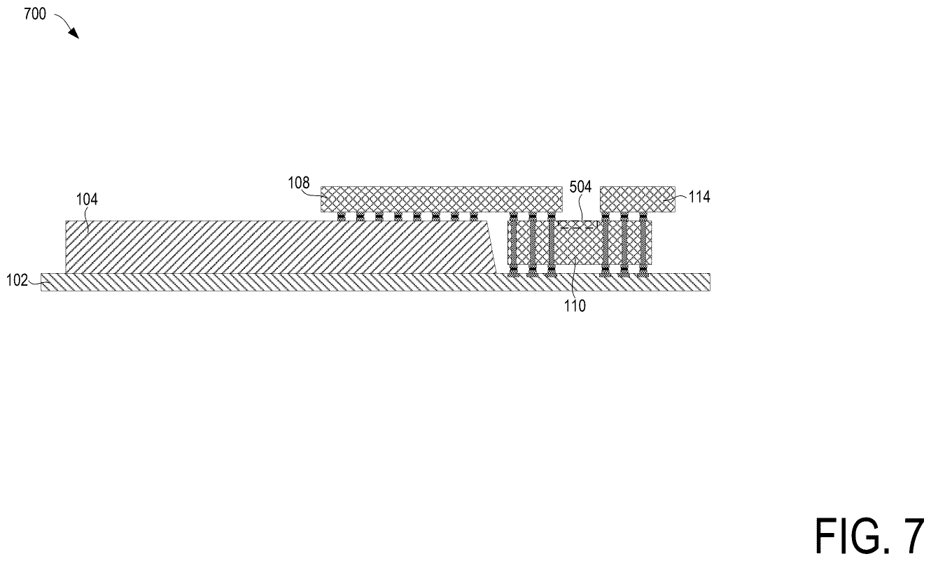

Referring now to FIG. 7, in one embodiment, an integrated circuit package 700 includes a substrate 102, one or more build-up layers 104, an EIC die 108 mounted on the build-up layers 104, a bridge dic 110 mounted on the substrate 102, and a PIC die 114 mounted on the bridge dic 110. The various components of the integrated circuit package 700 may be similar to or the same as the integrated circuit package 100 or other integrated circuit packages described herein, a detailed description of which will not be repeated in the interest of clarity. The PIC die 114 may be mounted directly on the bridge die 110, as shown in the figure. The bridge die 110 may include PIC driver circuitry 504. Additionally or alternatively, the EIC die 108 may include PIC driver circuitry 504. Mounting the PIC die 114 directly on the bridge die 110 may reduce the die count in the integrated circuit package 700. An interface on the PIC die 114, such as V-grooves, end-emitting waveguides, vertical-emitting waveguides, etc., may be on the bottom surface or the top surface of the PIC die 114, increasing the flexibility of possible arrangements. In some embodiments, through-die vias may be used to carry signals from the bridge die 110 to the top of the PIC dic 114.

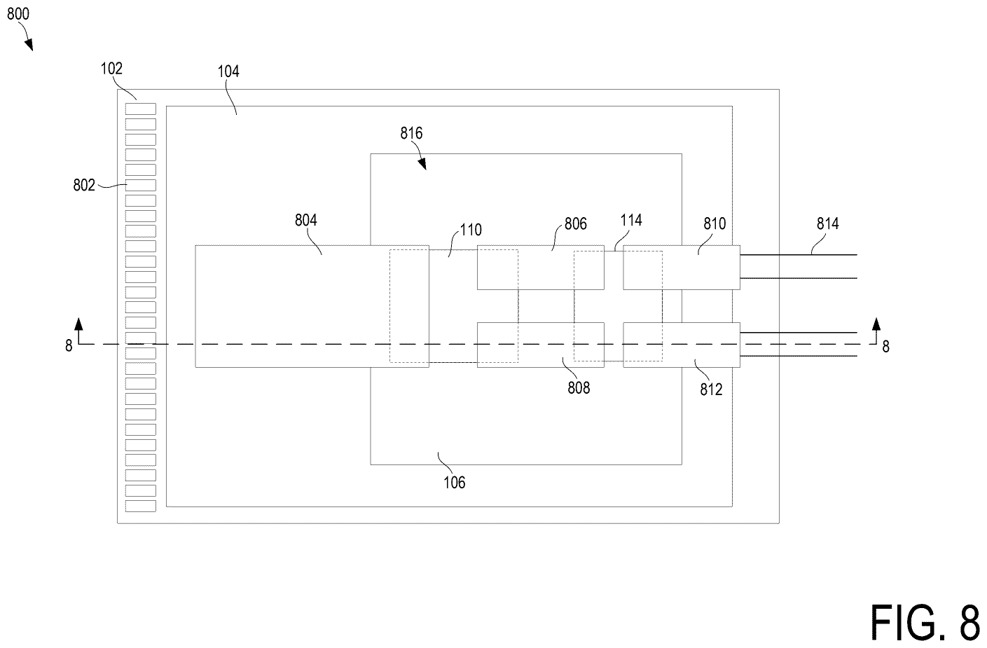

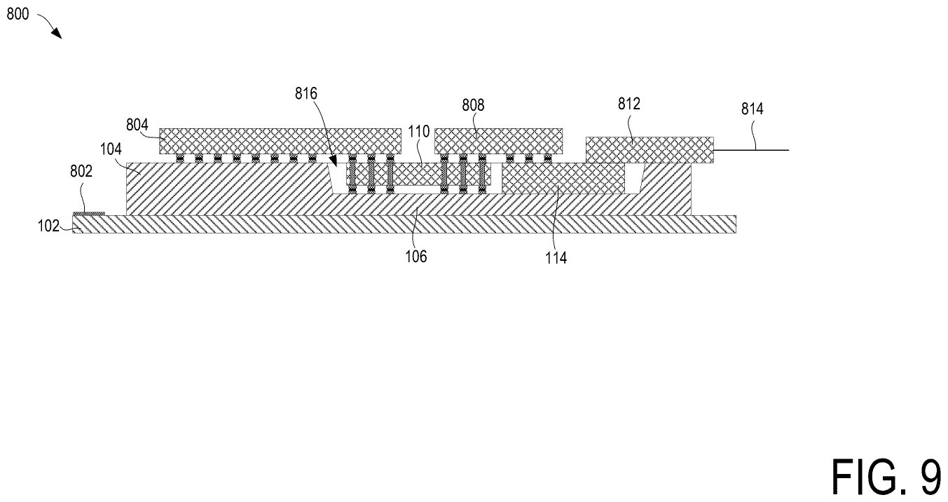

Referring now to FIGS. 8 and 9, in one embodiment, a transceiver module 800 includes a substrate 102 and one or more build-up layers 104 on the substrate 102. FIG. 8 shows a top-down view of the transceiver module, and FIG. 9 shows a cross-sectional view of the transceiver module 800. Edge connectors including one or more pads 802 are mounted on the substrate 102. In some embodiments, edge connectors including one or more pads 802 may be mounted one or more build-up lays. An EIC die 804 is mounted on the build-up layers 104. A cavity 816 is defined in the build-up layers 104. A bridge die 110 is mounted on the build-up layers 104 in the cavity 816. A PIC die 114 is also mounted on the build-up layers 104 in the cavity 816. A receive EIC dic 806 and a transmit EIC die 808 are each mounted on the bridge die 110 and the PIC die 114. A receive fiber attach unit 810 and a transmit fiber attach unit 812 are each mounted on the PIC die 114, and one or more fibers 814 extend from each of the fiber attach units 810, 812.

In use, the transceiver module 800 may be plugged into or otherwise connected to a communication port of a compute device. The transceiver module 800 may receive electronic data signals and convert them to optical signals sent on fibers 814 connected to the transmit fiber attach unit 812 and receive optical signals on fibers 814 connected to the receive fiber attach unit 810. The received optical signals may be amplified by a transimpedance amplifier on the receive EIC die 806. The EIC die 804 may be embodied as a digital signal processor 804 to process incoming and outgoing signals. The bridge die 110 may be used to provide power and/or data signals to the EIC die 804, the receive EIC die 806 and transimpedance amplifier on the receive EIC die 806, the transmit EIC die 808, etc. Use of the bridge die 110 may reduce the electrical path between various components compared to, e.g., using wire bonding, which may allow use of a smaller form factor. In some embodiments, the substrate 102 may include thermal vias, slugs, etc., to assist with heat dissipation. The transceiver module 800 may have any suitable form factor, such as QSFP-DD with dimensions 70.86 millimeters by 16.42 millimeters or OSFP with dimensions 78.59 by 20.65 millimeters. The transceiver module 800 may include other components not shown, such as a cover, housing, other electrical or optical components, etc.

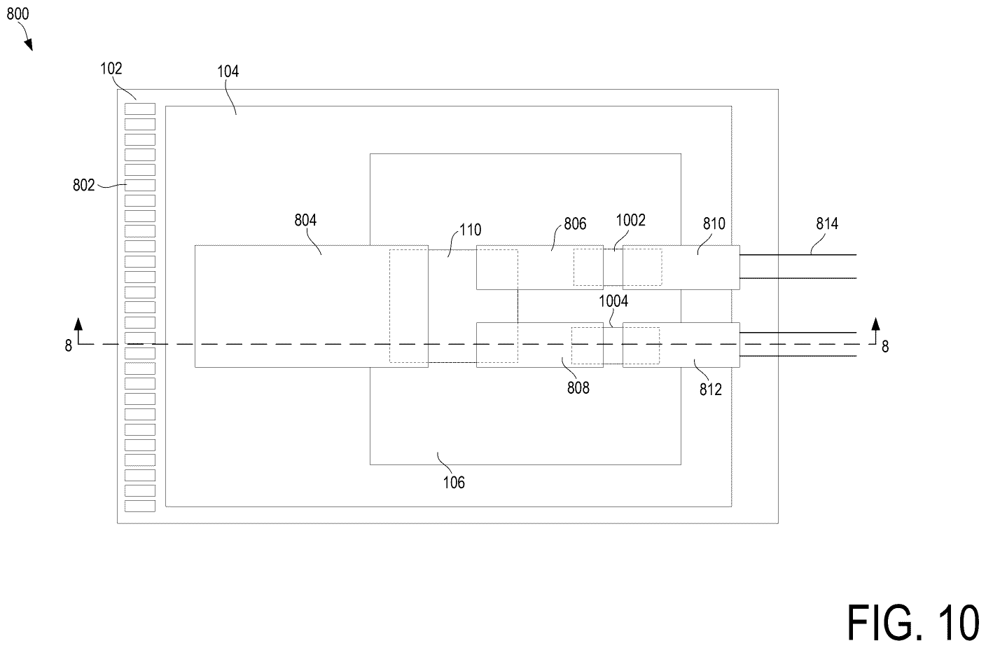

Referring now to FIG. 10, in one embodiment, a transceiver module 800 may include a separate receive PIC die 1002 and a transmit PIC die 1004, rather than a single PIC die 114 for both transmit and receive.

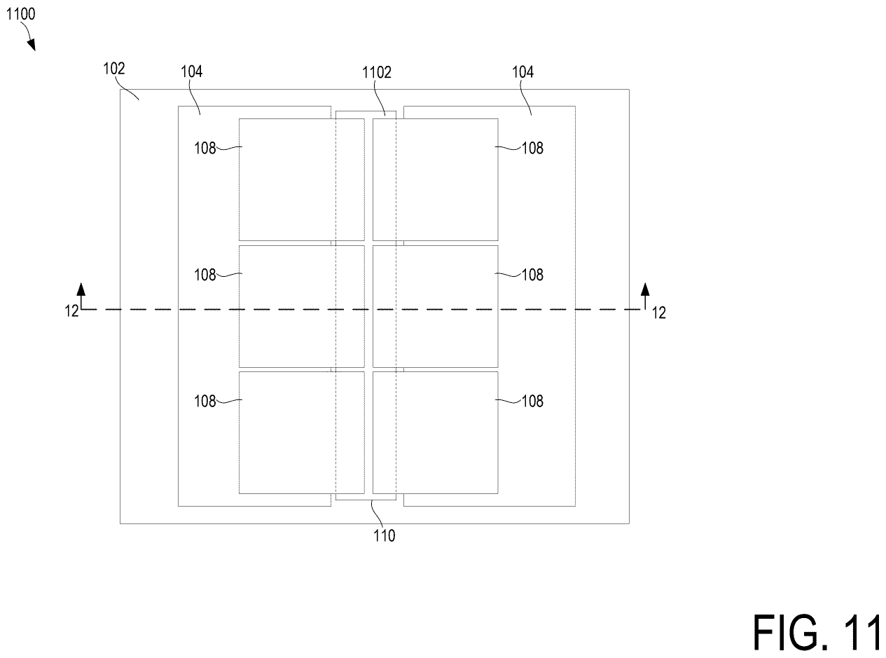

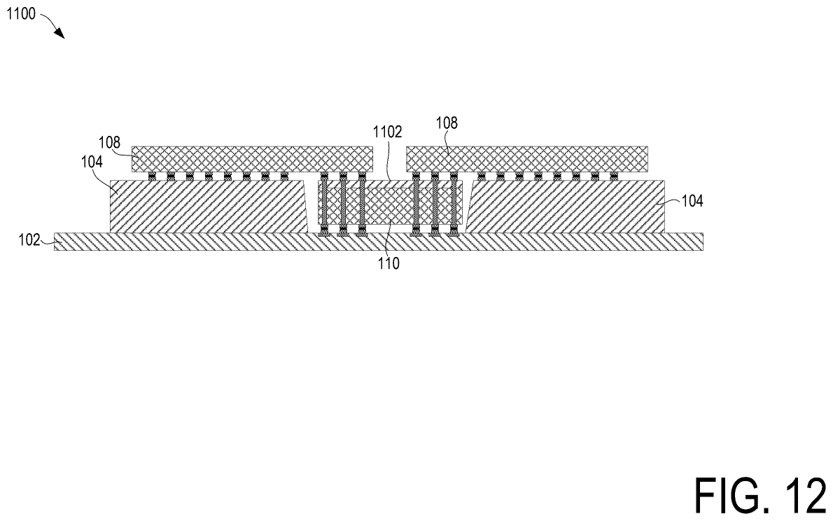

Referring now to FIGS. 11 and 12, in one embodiment, an integrated circuit package 1100 includes a substrate 102 and one or more build-up layers 104 on the substrate 102. FIG. 11 shows a top-down view of the integrated circuit package 1100, and FIG. 12 shows a cross-sectional view of the integrated circuit package 1100. A bridge die 110 is mounted on the substrate 102, and several EIC dies 108 are mounted on the bridge die 110. The bridge die 1102 includes a photonics layer 1102, such as a silicon photonics layer 1102. The photonics layer 1102 may have similar components and perform similar functions as the PIC die 114 described above. In use, the bridge die 110 may use the photonics layer 1102 to provide optical communication between the various EIC dies 108. In an illustrative embodiment, wavelength-division multiplexing may be used to use the same waveguides for communication between the various EIC dies 108. For example, microring resonators may be used to detect and modulate light at particular frequencies, allowing an EIC die 108 to modulate light that will only be detected by one other EIC die 108. The light source for the optical communication may be, e.g., a hybrid or off-chip laser. The EIC dies 108 may be arranged in, e.g., a ring network.

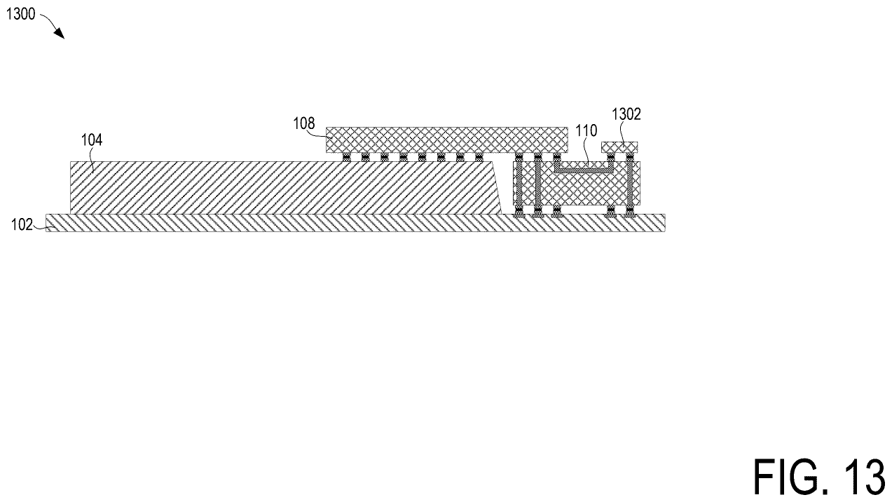

Referring now to FIG. 13, in one embodiment, an integrated circuit package 1300 includes a substrate 102, one or more build-up layers 104, a bridge die 110 mounted on the substrate 102, an EIC die 108 mounted on the build-up layers 104, and an array of micro-LED dies 1302 mounted on the bridge die 110. The EIC die 108 may include circuitry to drive micro-LEDs and/or photodetectors on the micro-LED dies 1302.

The micro-LED dies 1302 may be any suitable micro-LED, such as gallium nitride micro-LEDs 1302, quantum dot LEDs, single nanowire LED, etc. As used herein, a micro-LED refers to a light-emitting diode with a length and width of a light-emitting surface of less than 100 micrometers. In some embodiments, the length and/or width of a light-emitting surface of the micro-LEDs 1302 may be smaller, such as less than 10-50 micrometers. In the illustrative embodiment, the micro-LED dies 1302 are created on a separate substrate and transferred to a base die, the bridge die 110, or other dies. In some embodiments, other components such as a vertical cavity surface-emitting laser (VCSEL) or photodetector may be used in place of some or all of the micro-LED dies 1302. In some embodiments, the micro-LED dies 1302 may be mounted on the bridge die 110 and tested as a unit, allowing for the bridge die 110 and micro-LED dies to be integrated as a known good module.

It should be appreciated that various features of the various embodiments may be combined together in any suitable combination. For example, any PIC die 114 may include through-silicon vias 304, a shelf 106 may be integrated into any embodiment, features of any embodiment may be integrated into a transceiver module 700, etc.

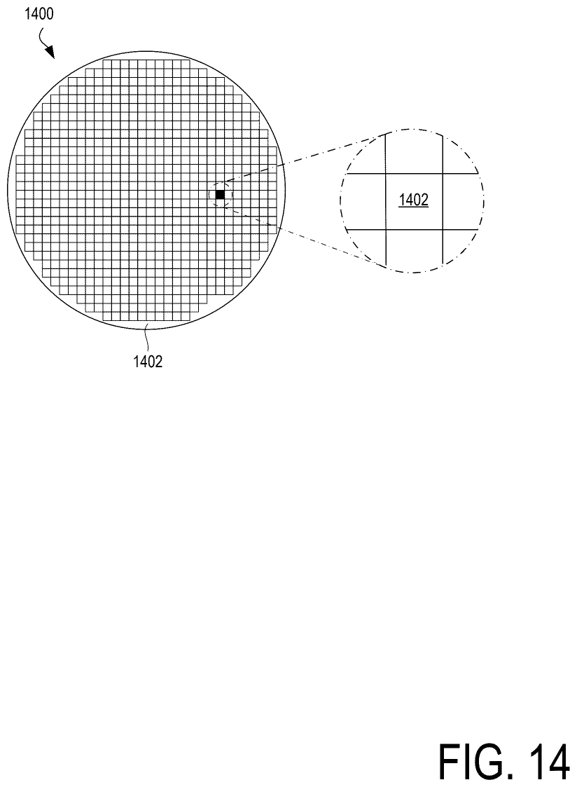

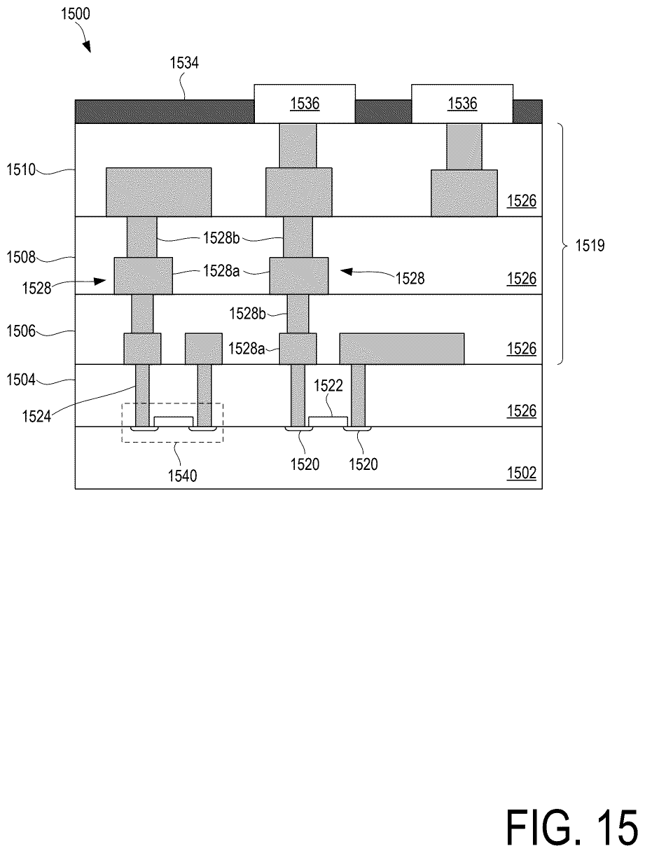

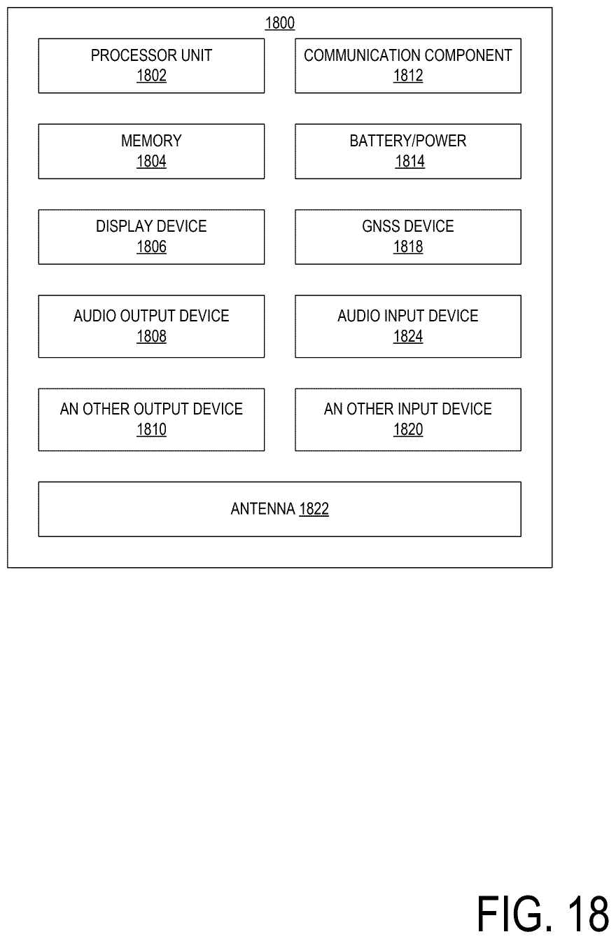

FIG. 14 is a top view of a wafer 1400 and dies 1402 that may be included in any of the integrated circuit packages 100, 400, 500, etc., disclosed herein (e.g., as any suitable ones of the dies 108, 110, 112, etc.). The wafer 1400 may be composed of semiconductor material and may include one or more dies 1402 having integrated circuit structures formed on a surface of the wafer 1400. The individual dies 1402 may be a repeating unit of an integrated circuit product that includes any suitable integrated circuit. After the fabrication of the semiconductor product is complete, the wafer 1400 may undergo a singulation process in which the dies 1402 are separated from one another to provide discrete “chips” of the integrated circuit product. The die 1402 may be any of the dies 108, 110, 112, etc., disclosed herein. The die 1402 may include one or more transistors (e.g., some of the transistors 1540 of FIG. 15, discussed below), supporting circuitry to route electrical signals to the transistors, passive components (e.g., signal traces, resistors, capacitors, or inductors), and/or any other integrated circuit components. In some embodiments, the wafer 1400 or the die 1402 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1402. For example, a memory array formed by multiple memory devices may be formed on a same die 1402 as a processor unit (e.g., the processor unit 1802 of FIG. 18) or other logic that is configured to store information in the memory devices or execute instructions stored in the memory array. Various ones of integrated circuit packages 100, 400, 500, etc., disclosed herein may be manufactured using a die-to-wafer assembly technique in which some dies 108, 110, 112, etc., are attached to a wafer 1400 that include others of the dies 108, 110, 112, etc., and the wafer 1400 is subsequently singulated.

FIG. 15 is a cross-sectional side view of an integrated circuit device 1500 that may be included in any of the integrated circuit packages 100, 400, 500, etc., disclosed herein (e.g., in any of the dies 108, 110, 112, etc.). One or more of the integrated circuit devices 1500 may be included in one or more dies 1402 (FIG. 14). The integrated circuit device 1500 may be formed on a die substrate 1502 (e.g., the wafer 1400 of FIG. 14) and may be included in a die (e.g., the die 1402 of FIG. 14). The die substrate 1502 may be a semiconductor substrate composed of semiconductor material systems including, for example, n-type or p-type materials systems (or a combination of both). The die substrate 1502 may include, for example, a crystalline substrate formed using a bulk silicon or a silicon-on-insulator (SOI) substructure. In some embodiments, the die substrate 1502 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1502. Although a few examples of materials from which the die substrate 1502 may be formed are described here, any material that may serve as a foundation for an integrated circuit device 1500 may be used. The die substrate 1502 may be part of a singulated die (e.g., the dies 1402 of FIG. 14) or a wafer (e.g., the wafer 1400 of FIG. 14).

The integrated circuit device 1500 may include one or more device layers 1504 disposed on the die substrate 1502. The device layer 1504 may include features of one or more transistors 1540 (e.g., metal oxide semiconductor field-effect transistors (MOSFETs)) formed on the die substrate 1502. The transistors 1540 may include, for example, one or more source and/or drain (S/D) regions 1520, a gate 1522 to control current flow between the S/D regions 1520, and one or more S/D contacts 1524 to route electrical signals to/from the S/D regions 1520. The transistors 1540 may include additional features not depicted for the sake of clarity, such as device isolation regions, gate contacts, and the like. The transistors 1540 are not limited to the type and configuration depicted in FIG. 15 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

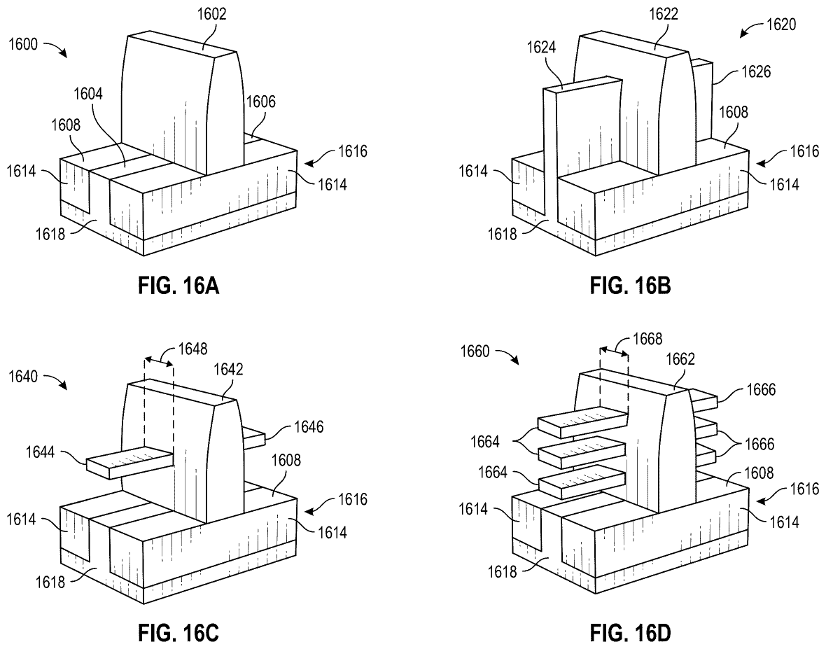

FIGS. 16A-16D are simplified perspective views of example planar, FinFET, gate-all-around, and stacked gate-all-around transistors. The transistors illustrated in FIGS. 16A-16D are formed on a substrate 1616 having a surface 1608. Isolation regions 1614 separate the source and drain regions of the transistors from other transistors and from a bulk region 1618 of the substrate 1616.

FIG. 16A is a perspective view of an example planar transistor 1600 comprising a gate 1602 that controls current flow between a source region 1604 and a drain region 1606. The transistor 1600 is planar in that the source region 1604 and the drain region 1606 are planar with respect to the substrate surface 1608.

FIG. 16B is a perspective view of an example FinFET transistor 1620 comprising a gate 1622 that controls current flow between a source region 1624 and a drain region 1626. The transistor 1620 is non-planar in that the source region 1624 and the drain region 1626 comprise “fins” that extend upwards from the substrate surface 1628. As the gate 1622 encompasses three sides of the semiconductor fin that extends from the source region 1624 to the drain region 1626, the transistor 1620 can be considered a tri-gate transistor. FIG. 16B illustrates one S/D fin extending through the gate 1622, but multiple S/D fins can extend through the gate of a FinFET transistor.

FIG. 16C is a perspective view of a gate-all-around (GAA) transistor 1640 comprising a gate 1642 that controls current flow between a source region 1644 and a drain region 1646. The transistor 1640 is non-planar in that the source region 1644 and the drain region 1646 are elevated from the substrate surface 1628.

FIG. 16D is a perspective view of a GAA transistor 1660 comprising a gate 1662 that controls current flow between multiple elevated source regions 1664 and multiple elevated drain regions 1666. The transistor 1660 is a stacked GAA transistor as the gate controls the flow of current between multiple elevated S/D regions stacked on top of each other. The transistors 1640 and 1660 are considered gate-all-around transistors as the gates encompass all sides of the semiconductor portions that extends from the source regions to the drain regions. The transistors 1640 and 1660 can alternatively be referred to as nanowire, nanosheet, or nanoribbon transistors depending on the width (e.g., widths 1648 and 1668 of transistors 1640 and 1660, respectively) of the semiconductor portions extending through the gate.

Returning to FIG. 15, a transistor 1540 may include a gate 1522 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1540 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1540 along the source-channel-drain direction, the gate electrode may consist of a U-shaped structure that includes a bottom portion substantially parallel to the surface of the die substrate 1502 and two sidewall portions that are substantially perpendicular to the top surface of the die substrate 1502. In other embodiments, at least one of the metal layers that form the gate electrode may simply be a planar layer that is substantially parallel to the top surface of the die substrate 1502 and does not include sidewall portions substantially perpendicular to the top surface of the die substrate 1502. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1520 may be formed within the die substrate 1502 adjacent to the gate 1522 of individual transistors 1540. The S/D regions 1520 may be formed using an implantation/diffusion process or an etching/deposition process, for example. In the former process, dopants such as boron, aluminum, antimony, phosphorous, or arsenic may be ion-implanted into the die substrate 1502 to form the S/D regions 1520. An annealing process that activates the dopants and causes them to diffuse farther into the die substrate 1502 may follow the ion-implantation process. In the latter process, the die substrate 1502 may first be etched to form recesses at the locations of the S/D regions 1520. An epitaxial deposition process may then be carried out to fill the recesses with material that is used to fabricate the S/D regions 1520. In some implementations, the S/D regions 1520 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1520 may be formed using one or more alternate semiconductor materials such as germanium or a group III-V material or alloy. In further embodiments, one or more layers of metal and/or metal alloys may be used to form the S/D regions 1520.

Electrical signals, such as power and/or input/output (I/O) signals, may be routed to and/or from the devices (e.g., transistors 1540) of the device layer 1504 through one or more interconnect layers disposed on the device layer 1504 (illustrated in FIG. 15 as interconnect layers 1506-1510). For example, electrically conductive features of the device layer 1504 (e.g., the gate 1522 and the S/D contacts 1524) may be electrically coupled with the interconnect structures 1528 of the interconnect layers 1506-1510. The one or more interconnect layers 1506-1510 may form a metallization stack (also referred to as an “ILD stack”) 1519 of the integrated circuit device 1500.

The interconnect structures 1528 may be arranged within the interconnect layers 1506-1510 to route electrical signals according to a wide variety of designs; in particular, the arrangement is not limited to the particular configuration of interconnect structures 1528 depicted in FIG. 15. Although a particular number of interconnect layers 1506-1510 is depicted in FIG. 15, embodiments of the present disclosure include integrated circuit devices having more or fewer interconnect layers than depicted.

In some embodiments, the interconnect structures 1528 may include lines 1528a and/or vias 1528b filled with an electrically conductive material such as a metal. The lines 1528a may be arranged to route electrical signals in a direction of a plane that is substantially parallel with a surface of the die substrate 1502 upon which the device layer 1504 is formed. For example, the lines 1528a may route electrical signals in a direction in and out of the page and/or in a direction across the page. The vias 1528b may be arranged to route electrical signals in a direction of a plane that is substantially perpendicular to the surface of the die substrate 1502 upon which the device layer 1504 is formed. In some embodiments, the vias 1528b may electrically couple lines 1528a of different interconnect layers 1506-1510 together.

The interconnect layers 1506-1510 may include a dielectric material 1526 disposed between the interconnect structures 1528, as shown in FIG. 15. In some embodiments, dielectric material 1526 disposed between the interconnect structures 1528 in different ones of the interconnect layers 1506-1510 may have different compositions; in other embodiments, the composition of the dielectric material 1526 between different interconnect layers 1506-1510 may be the same. The device layer 1504 may include a dielectric material 1526 disposed between the transistors 1540 and a bottom layer of the metallization stack as well. The dielectric material 1526 included in the device layer 1504 may have a different composition than the dielectric material 1526 included in the interconnect layers 1506-1510; in other embodiments, the composition of the dielectric material 1526 in the device layer 1504 may be the same as a dielectric material 1526 included in any one of the interconnect layers 1506-1510.

A first interconnect layer 1506 (referred to as Metal 1 or “M1”) may be formed directly on the device layer 1504. In some embodiments, the first interconnect layer 1506 may include lines 1528a and/or vias 1528b, as shown. The lines 1528a of the first interconnect layer 1506 may be coupled with contacts (e.g., the S/D contacts 1524) of the device layer 1504. The vias 1528b of the first interconnect layer 1506 may be coupled with the lines 1528a of a second interconnect layer 1508.

The second interconnect layer 1508 (referred to as Metal 2 or “M2”) may be formed directly on the first interconnect layer 1506. In some embodiments, the second interconnect layer 1508 may include via 1528b to couple the lines 1528 of the second interconnect layer 1508 with the lines 1528a of a third interconnect layer 1510. Although the lines 1528a and the vias 1528b are structurally delineated with a line within individual interconnect layers for the sake of clarity, the lines 1528a and the vias 1528b may be structurally and/or materially contiguous (e.g., simultaneously filled during a dual-damascene process) in some embodiments.

The third interconnect layer 1510 (referred to as Metal 3 or “M3”) (and additional interconnect layers, as desired) may be formed in succession on the second interconnect layer 1508 according to similar techniques and configurations described in connection with the second interconnect layer 1508 or the first interconnect layer 1506. In some embodiments, the interconnect layers that are “higher up” in the metallization stack 1519 in the integrated circuit device 1500 (i.e., farther away from the device layer 1504) may be thicker that the interconnect layers that are lower in the metallization stack 1519, with lines 1528a and vias 1528b in the higher interconnect layers being thicker than those in the lower interconnect layers.

The integrated circuit device 1500 may include a solder resist material 1534 (e.g., polyimide or similar material) and one or more conductive contacts 1536 formed on the interconnect layers 1506-1510. In FIG. 15, the conductive contacts 1536 are illustrated as taking the form of bond pads. The conductive contacts 1536 may be electrically coupled with the interconnect structures 1528 and configured to route the electrical signals of the transistor(s) 1540 to external devices. For example, solder bonds may be formed on the one or more conductive contacts 1536 to mechanically and/or electrically couple an integrated circuit die including the integrated circuit device 1500 with another component (e.g., a printed circuit board). The integrated circuit device 1500 may include additional or alternate structures to route the electrical signals from the interconnect layers 1506-1510; for example, the conductive contacts 1536 may include other analogous features (e.g., posts) that route the electrical signals to external components. The conductive contacts 1536 may serve as the conductive contacts 306 or 802, as appropriate.

In some embodiments in which the integrated circuit device 1500 is a double-sided die, the integrated circuit device 1500 may include another metallization stack (not shown) on the opposite side of the device layer(s) 1504. This metallization stack may include multiple interconnect layers as discussed above with reference to the interconnect layers 1506-1510, to provide conductive pathways (e.g., including conductive lines and vias) between the device layer(s) 1504 and additional conductive contacts (not shown) on the opposite side of the integrated circuit device 1500 from the conductive contacts 1536. These additional conductive contacts may serve as the conductive contacts 306 or 802, as appropriate.

In other embodiments in which the integrated circuit device 1500 is a double-sided die, the integrated circuit device 1500 may include one or more through silicon vias (TSVs) through the die substrate 1502; these TSVs may make contact with the device layer(s) 1504, and may provide conductive pathways between the device layer(s) 1504 and additional conductive contacts (not shown) on the opposite side of the integrated circuit device 1500 from the conductive contacts 1536. These additional conductive contacts may serve as the conductive contacts 306 or 802, as appropriate. In some embodiments, TSVs extending through the substrate can be used for routing power and ground signals from conductive contacts on the opposite side of the integrated circuit device 1500 from the conductive contacts 1536 to the transistors 1540 and any other components integrated into the die 1500, and the metallization stack 1519 can be used to route I/O signals from the conductive contacts 1536 to transistors 1540 and any other components integrated into the die 1500.

Multiple integrated circuit devices 1500 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

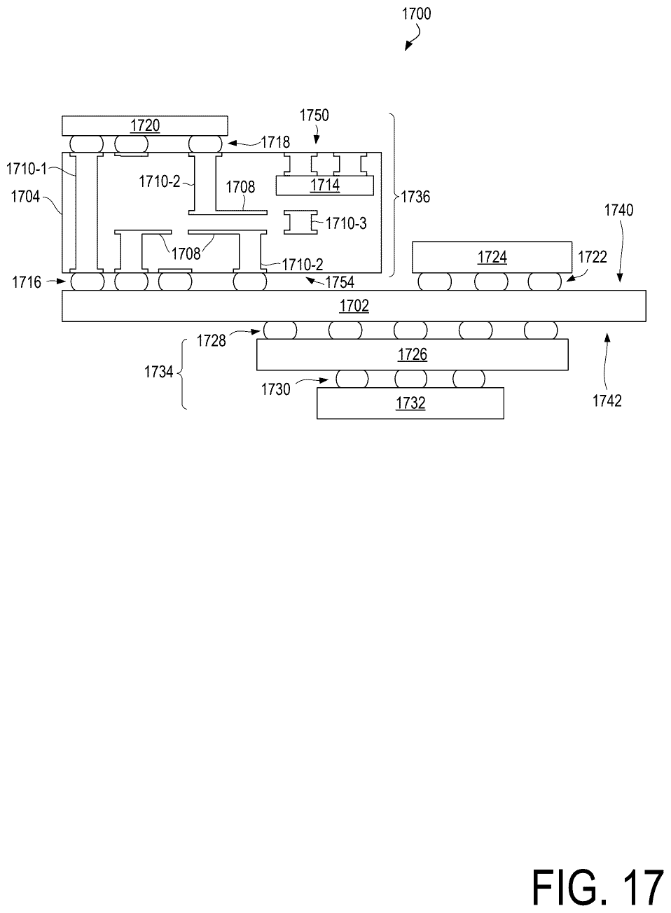

FIG. 17 is a cross-sectional side view of an integrated circuit device assembly 1700 that may include any of the integrated circuit packages 100, 400, 500, etc., disclosed herein. In some embodiments, the integrated circuit device assembly 1700 may be an integrated circuit packages 100, 400, 500, etc. The integrated circuit device assembly 1700 includes a number of components disposed on a circuit board 1702 (which may be a motherboard, system board, mainboard, etc.). The integrated circuit device assembly 1700 includes components disposed on a first face 1740 of the circuit board 1702 and an opposing second face 1742 of the circuit board 1702; generally, components may be disposed on one or both faces 1740 and 1742. Any of the integrated circuit components discussed below with reference to the integrated circuit device assembly 1700 may take the form of any suitable ones of the embodiments of the integrated circuit packages 100, 400, 500, etc., disclosed herein.

In some embodiments, the circuit board 1702 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate. In some embodiments the circuit board 1702 may be embodied as or otherwise include, for example, the substrate 102. The integrated circuit device assembly 1700 illustrated in FIG. 17 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 17), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. The coupling components 1716 may serve as the coupling components illustrated or described for any of the substrate assembly or substrate assembly components described herein, as appropriate.

The package-on-interposer structure 1736 may include an integrated circuit component 1720 coupled to an interposer 1704 by coupling components 1718. The coupling components 1718 may take any suitable form for the application, such as the forms discussed above with reference to the coupling components 1716. Although a single integrated circuit component 1720 is shown in FIG. 17, multiple integrated circuit components may be coupled to the interposer 1704; indeed, additional interposers may be coupled to the interposer 1704. The interposer 1704 may provide an intervening substrate used to bridge the circuit board 1702 and the integrated circuit component 1720.

The integrated circuit component 1720 may be a packaged or unpacked integrated circuit product that includes one or more integrated circuit dies (e.g., the die 1402 of FIG. 14, the integrated circuit device 1500 of FIG. 15) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1720, a single monolithic integrated circuit die comprises solder bumps attached to contacts on the die. The solder bumps allow the die to be directly attached to the interposer 1704. The integrated circuit component 1720 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1720 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1720 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1720 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1704 may spread connections to a wider pitch or reroute a connection to a different connection. For example, the interposer 1704 may couple the integrated circuit component 1720 to a set of ball grid array (BGA) conductive contacts of the coupling components 1716 for coupling to the circuit board 1702. In the embodiment illustrated in FIG. 17, the integrated circuit component 1720 and the circuit board 1702 are attached to opposing sides of the interposer 1704; in other embodiments, the integrated circuit component 1720 and the circuit board 1702 may be attached to a same side of the interposer 1704. In some embodiments, three or more components may be interconnected by way of the interposer 1704.

In some embodiments, the interposer 1704 may be formed as a PCB, including multiple metal layers separated from one another by layers of dielectric material and interconnected by electrically conductive vias. In some embodiments, the interposer 1704 may be formed of an epoxy resin, a fiberglass-reinforced epoxy resin, an epoxy resin with inorganic fillers, a ceramic material, or a polymer material such as polyimide. In some embodiments, the interposer 1704 may be formed of alternate rigid or flexible materials that may include the same materials described above for use in a semiconductor substrate, such as silicon, germanium, and other group III-V and group IV materials. The interposer 1704 may include metal interconnects 1708 and vias 1710, including but not limited to through hole vias 1710-1 (that extend from a first face 1750 of the interposer 1704 to a second face 1754 of the interposer 1704), blind vias 1710-2 (that extend from the first or second faces 1750 or 1754 of the interposer 1704 to an internal metal layer), and buried vias 1710-3 (that connect internal metal layers).

In some embodiments, the interposer 1704 can comprise a silicon interposer. Through silicon vias (TSV) extending through the silicon interposer can connect connections on a first face of a silicon interposer to an opposing second face of the silicon interposer. In some embodiments, an interposer 1704 comprising a silicon interposer can further comprise one or more routing layers to route connections on a first face of the interposer 1704 to an opposing second face of the interposer 1704.

The interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1704. The package-on-interposer structure 1736 may take the form of any of the package-on-interposer structures known in the art.

The integrated circuit device assembly 1700 may include an integrated circuit component 1724 coupled to the first face 1740 of the circuit board 1702 by coupling components 1722. The coupling components 1722 may take the form of any of the embodiments discussed above with reference to the coupling components 1716, and the integrated circuit component 1724 may take the form of any of the embodiments discussed above with reference to the integrated circuit component 1720.

The integrated circuit device assembly 1700 illustrated in FIG. 17 includes a package-on-package structure 1734 coupled to the second face 1742 of the circuit board 1702 by coupling components 1728. The package-on-package structure 1734 may include an integrated circuit component 1726 and an integrated circuit component 1732 coupled together by coupling components 1730 such that the integrated circuit component 1726 is disposed between the circuit board 1702 and the integrated circuit component 1732. The coupling components 1728 and 1730 may take the form of any of the embodiments of the coupling components 1716 discussed above, and the integrated circuit components 1726 and 1732 may take the form of any of the embodiments of the integrated circuit component 1720 discussed above. The package-on-package structure 1734 may be configured in accordance with any of the package-on-package structures known in the art.

FIG. 18 is a block diagram of an example electrical device 1800 that may include one or more of the integrated circuit packages 100, 400, 500, etc., disclosed herein. For example, any suitable ones of the components of the electrical device 1800 may include one or more of the integrated circuit device assemblies 1700, integrated circuit components 1720, integrated circuit devices 1500, or integrated circuit dies 1402 disclosed herein, and may be arranged in any of the integrated circuit packages 100, 400, 500, etc., disclosed herein. A number of components are illustrated in FIG. 18 as included in the electrical device 1800, but any one or more of these components may be omitted or duplicated, as suitable for the application. In some embodiments, some or all of the components included in the electrical device 1800 may be attached to one or more motherboards mainboards, or system boards. In some embodiments, one or more of these components are fabricated onto a single system-on-a-chip (SoC) die.

Additionally, in various embodiments, the electrical device 1800 may not include one or more of the components illustrated in FIG. 18, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include one or more processor units 1802 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1802 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1800 may include a memory 1804, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1804 may include memory that is located on the same integrated circuit die as the processor unit 1802. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 1800 can comprise one or more processor units 1802 that are heterogeneous or asymmetric to another processor unit 1802 in the electrical device 1800. There can be a variety of differences between the processing units 1802 in a system in terms of a spectrum of metrics of merit including architectural, microarchitectural, thermal, power consumption characteristics, and the like. These differences can effectively manifest themselves as asymmetry and heterogeneity among the processor units 1802 in the electrical device 1800.

In some embodiments, the electrical device 1800 may include a communication component 1812 (e.g., one or more communication components). For example, the communication component 1812 can manage wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication component 1812 may manage wired communications, such as electrical, optical, or any other suitable communication protocols (e.g., IEEE 802.3 Ethernet standards). As noted above, the communication component 1812 may include multiple communication components. For instance, a first communication component 1812 may be dedicated to shorter-range wireless communications such as Wi-Fi or Bluetooth, and a second communication component 1812 may be dedicated to longer-range wireless communications such as global positioning system (GPS), EDGE, GPRS, CDMA, WiMAX, LTE, EV-DO, or others. In some embodiments, a first communication component 1812 may be dedicated to wireless communications, and a second communication component 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any embedded or wired or wirelessly connected external device that generates an audible indicator, such as speakers, headsets, or earbuds.

The electrical device 1800 may include an audio input device 1824 (or corresponding interface circuitry, as discussed above). The audio input device 1824 may include any embedded or wired or wirelessly connected device that generates a signal representative of a sound, such as microphones, microphone arrays, or digital instruments (e.g., instruments having a musical instrument digital interface (MIDI) output). The electrical device 1800 may include a Global Navigation Satellite System (GNSS) device 1818 (or corresponding interface circuitry, as discussed above), such as a Global Positioning System (GPS) device. The GNSS device 1818 may be in communication with a satellite-based system and may determine a geolocation of the electrical device 1800 based on information received from one or more GNSS satellites, as known in the art.

The electrical device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include an other input device 1820 (or corresponding interface circuitry, as discussed above). Examples of the other input device 1820 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1800 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1800 may be any other electronic device that processes data. In some embodiments, the electrical device 1800 may comprise multiple discrete physical components. Given the range of devices that the electrical device 1800 can be manifested as in various embodiments, in some embodiments, the electrical device 1800 can be referred to as a computing device or a computing system.

### Examples

Illustrative examples of the technologies disclosed herein are provided below. An embodiment of the technologies may include any one or more, and any combination of, the examples described below.

Example 1 includes an apparatus comprising a substrate; one or more build-up layers adjacent the substrate; a first electronic integrated circuit (EIC) die mounted on the one or more build-up layers; a photonic integrated circuit (PIC) die mounted on the substrate; a second EIC die mounted on the PIC die; and a bridge die electrically coupled to the substrate, the first EIC die, and the second EIC die, wherein a through-silicon via is defined in the bridge die, wherein the through-silicon via electrically couples a pad defined on the substrate to a pad defined on the second EIC die, wherein the pad defined on the second EIC die is electrically coupled to the PIC die.

Example 2 includes the subject matter of Example 1, and wherein the through-silicon via comprises a conductive power pathway.

Example 3 includes the subject matter of any of Examples 1 and 2, and wherein a lateral distance between the PIC die and the bridge die is less than 50 micrometers.

Example 4 includes the subject matter of any of Examples 1-3, and wherein the one or more build-up layers comprises a first surface, wherein the first EIC die is mounted on the first surface, wherein a cavity is defined in the one or more build-up layers, wherein a second surface of the one or more build-up layers is defined at an end of the cavity, wherein the bridge die is mounted on the second surface.

Example 5 includes the subject matter of any of Examples 1-4, and wherein the bridge die is mounted on the substrate.

Example 6 includes the subject matter of any of Examples 1-5, and wherein the apparatus is a transceiver module, wherein the first EIC die comprises a digital signal processor die, wherein one or more optical fibers are coupled to the PIC die.

Example 7 includes the subject matter of any of Examples 1-6, and wherein the substrate comprises a solid layer of glass rectangular in shape in plan view.

Example 8 includes the subject matter of any of Examples 1-7, and wherein the PIC die comprises a first waveguide, a modulator coupled to the first waveguide, a second waveguide, and a photodetector coupled to the second waveguide.

Example 9 includes the subject matter of any of Examples 1-8, and wherein the second EIC die is an input/output EIC die, wherein the input/output EIC die comprises PIC driver circuitry.

Example 10 includes the subject matter of any of Examples 1-9, and wherein the bridge die is to carry data signals between the first EIC die and the second EIC die.

Example 11 includes an apparatus comprising a substrate; one or more build-up layers adjacent the substrate; a photonic integrated circuit (PIC) die mounted on the substrate; an electronic integrated circuit (EIC) die mounted on the one or more build-up layers and the PIC die; and a bridge die electrically coupled to the substrate and the EIC die, wherein a through-silicon via is defined in the bridge die, wherein the through-silicon via electrically couples a pad defined on the substrate to a pad defined on the EIC die, wherein the pad defined on the EIC die is electrically coupled to the PIC die.

Example 12 includes the subject matter of Example 11, and wherein the bridge die is configured to supply power from the substrate, through the through-silicon via, to the PIC dic.

Example 13 includes the subject matter of any of Examples 11 and 12, and wherein a lateral distance between the PIC die and the bridge die is less than 50 micrometers.

Example 14 includes the subject matter of any of Examples 11-13, and wherein the bridge die is mounted on the substrate.

Example 15 includes the subject matter of any of Examples 11-14, and wherein the apparatus is a transceiver module, wherein the EIC die comprises a digital signal processor die, wherein one or more optical fibers are coupled to the PIC die.

Example 16 includes the subject matter of any of Examples 11-15, and wherein the substrate comprises a solid layer of glass rectangular in shape in plan view.

Example 17 includes the subject matter of any of Examples 11-16, and wherein the PIC die comprises a first waveguide, a modulator coupled to the first waveguide, a second waveguide, and a photodetector coupled to the second waveguide.

Example 18 includes an apparatus comprising a substrate; one or more build-up layers adjacent the substrate; an electronic integrated circuit (EIC) die mounted on the one or more build-up layers; a bridge die electrically coupled to the substrate and the EIC die; and a photonic integrated circuit (PIC) die mounted on the bridge die, wherein a through-silicon via is defined in the bridge die, wherein the through-silicon via electrically couples a pad defined on the substrate to a pad defined on the PIC die.

Example 19 includes the subject matter of Example 18, and wherein a through-silicon via is defined in the PIC die, wherein the through-silicon via of the PIC die is connected to the pad defined on the PIC die.

Example 20 includes the subject matter of any of Examples 18 and 19, and wherein the bridge die comprises PIC driver circuitry to drive one or more components of the PIC die.

Example 21 includes the subject matter of any of Examples 18-20, and wherein the bridge die is configured to supply power from the substrate, through the through-silicon via, to the PIC dic.

Example 22 includes the subject matter of any of Examples 18-21, and wherein the bridge die is mounted on the substrate.

Example 23 includes the subject matter of any of Examples 18-22, and wherein the apparatus is a transceiver module, wherein the EIC die comprises a digital signal processor die, wherein one or more optical fibers are coupled to the PIC die.

Example 24 includes the subject matter of any of Examples 18-23, and wherein the substrate comprises a solid layer of glass rectangular in shape in plan view.

Example 25 includes the subject matter of any of Examples 18-24, and wherein the PIC die comprises a first waveguide, a modulator coupled to the first waveguide, a second waveguide, and a photodetector coupled to the second waveguide.

Example 26 includes an apparatus comprising a substrate; one or more build-up layers adjacent the substrate; a bridge die electrically coupled to the substrate, wherein the bridge die comprises a silicon photonics layer; a first electronic integrated circuit (EIC) die mounted on the one or more build-up layers and the bridge die; and a second EIC die mounted on the one or more build-up layers and the bridge die.

Example 27 includes the subject matter of Example 26, and wherein the first EIC die comprises PIC driver circuitry to create an optical signal on the PIC die to be sent to the second EIC die, wherein the second EIC die comprises PIC driver circuitry to receive the optical signal.

Example 28 includes the subject matter of any of Examples 26 and 27, and wherein a waveguide is defined in the silicon photonics layer, wherein the silicon photonics layer comprises a plurality of microring resonators coupled to the waveguide, wherein individual microring resonators of the plurality of microring resonators resonate at a different wavelength channel.

Example 29 includes the subject matter of any of Examples 26-28, and wherein the bridge die is configured to supply power from the substrate, through a through-silicon via defined in the bridge die, to the silicon photonics layer.

Example 30 includes the subject matter of any of Examples 26-29, and wherein the bridge die is mounted on the substrate.

Example 31 includes the subject matter of any of Examples 26-30, and wherein the substrate comprises a solid layer of glass rectangular in shape in plan view.

Example 32 includes the subject matter of any of Examples 26-31, and wherein the silicon photonics layer comprises a first waveguide, a modulator coupled to the first waveguide, a second waveguide, and a photodetector coupled to the second waveguide.

Example 33 includes an apparatus comprising a substrate; one or more build-up layers adjacent the substrate; an electronic integrated circuit (EIC) die mounted on the one or more build-up layers; a bridge die electrically coupled to the substrate and the EIC die; and a plurality of micro-LED dies die mounted on the bridge die, wherein a through-silicon via is defined in the bridge die, wherein the through-silicon via electrically couples a pad defined on the substrate to a pad defined on one of the plurality of micro-LED dies.

Example 34 includes the subject matter of Example 33, and wherein the bridge die is configured to supply power from the substrate, through the through-silicon via, to the plurality of micro-LED dies.

Example 35 includes the subject matter of any of Examples 33 and 34, and wherein the bridge die is mounted on the substrate.

Example 36 includes the subject matter of any of Examples 33-35, and wherein the substrate comprises a solid layer of glass rectangular in shape in plan view.

Example 37 includes an apparatus comprising a substrate; one or more build-up layers adjacent the substrate; an electronic integrated circuit (EIC) die mounted on the one or more build-up layers; a photonic integrated circuit (PIC) die; a bridge die, wherein a through-silicon via is defined in the bridge die; and means for providing power from the substrate, through the through-silicon via, to the PIC die.

Example 38 includes the subject matter of Example 37, and wherein the bridge die is configured to supply power from the substrate, through the through-silicon via, to the PIC die.

Example 39 includes the subject matter of any of Examples 37 and 38, and wherein a lateral distance between the PIC die and the bridge die is less than 50 micrometers.

Example 40 includes the subject matter of any of Examples 37-39, and wherein the bridge die is mounted on the substrate.

Example 41 includes the subject matter of any of Examples 37-40, and wherein the apparatus is a transceiver module, wherein the EIC die comprises a digital signal processor die, wherein one or more optical fibers are coupled to the PIC die.

Example 42 includes the subject matter of any of Examples 37-41, and wherein the substrate comprises a solid layer of glass rectangular in shape in plan view.

Example 43 includes the subject matter of any of Examples 37-42, and wherein the PIC die comprises a first waveguide, a modulator coupled to the first waveguide, a second waveguide, and a photodetector coupled to the second waveguide.

1. An apparatus comprising:
a substrate;
one or more build-up layers adjacent the substrate;
a first electronic integrated circuit (EIC) die mounted on the one or more build-up layers;
a photonic integrated circuit (PIC) die mounted on the substrate;
a second EIC die mounted on the PIC die; and
a bridge die electrically coupled to the substrate, the first EIC die, and the second EIC die,
wherein a through-silicon via is defined in the bridge die, wherein the through-silicon via electrically couples a pad defined on the substrate to a pad defined on the second EIC die, wherein the pad defined on the second EIC die is electrically coupled to the PIC die.

2. The apparatus of claim 1, wherein the through-silicon via comprises a conductive power pathway.

3. The apparatus of claim 1, wherein a lateral distance between the PIC die and the bridge die is less than 50 micrometers.

4. The apparatus of claim 1, wherein the one or more build-up layers comprises a first surface, wherein the first EIC die is mounted on the first surface, wherein a cavity is defined in the one or more build-up layers, wherein a second surface of the one or more build-up layers is defined at an end of the cavity, wherein the bridge die is mounted on the second surface.

5. The apparatus of claim 1, wherein the bridge die is mounted on the substrate.

6. The apparatus of claim 1, wherein the apparatus is a transceiver module, wherein the first EIC die comprises a digital signal processor die, wherein one or more optical fibers are coupled to the PIC die.

7. The apparatus of claim 1, wherein the substrate comprises a solid layer of glass rectangular in shape in plan view.

8. The apparatus of claim 1, wherein the PIC die comprises a first waveguide, a modulator coupled to the first waveguide, a second waveguide, and a photodetector coupled to the second waveguide.

9. The apparatus of claim 1, wherein the second EIC die is an input/output EIC die, wherein the input/output EIC die comprises PIC driver circuitry.

10. The apparatus of claim 1, wherein the bridge die is to carry data signals between the first EIC die and the second EIC die.

11. An apparatus comprising:
a substrate;
one or more build-up layers adjacent the substrate;
a photonic integrated circuit (PIC) die mounted on the substrate;
an electronic integrated circuit (EIC) die mounted on the one or more build-up layers and the PIC die; and
a bridge die electrically coupled to the substrate and the EIC die,
wherein a through-silicon via is defined in the bridge die, wherein the through-silicon via electrically couples a pad defined on the substrate to a pad defined on the EIC die, wherein the pad defined on the EIC die is electrically coupled to the PIC die.

12. The apparatus of claim 11, wherein the bridge die is configured to supply power from the substrate, through the through-silicon via, to the PIC die.

13. The apparatus of claim 11, wherein a lateral distance between the PIC die and the bridge die is less than 50 micrometers.

14. The apparatus of claim 11, wherein the bridge die is mounted on the substrate.

15. The apparatus of claim 11, wherein the substrate comprises a solid layer of glass rectangular in shape in plan view.

16. An apparatus comprising:
a substrate;
one or more build-up layers adjacent the substrate;
an electronic integrated circuit (EIC) die mounted on the one or more build-up layers;
a photonic integrated circuit (PIC) die;
a bridge die, wherein a through-silicon via is defined in the bridge die; and
means for providing power from the substrate, through the through-silicon via, to the PIC die.

17. The apparatus of claim 16, wherein the bridge die is configured to supply power from the substrate, through the through-silicon via, to the PIC die.

18. The apparatus of claim 16, wherein a lateral distance between the PIC die and the bridge die is less than 50 micrometers.

19. The apparatus of claim 16, wherein the substrate comprises a solid layer of glass rectangular in shape in plan view.

20. The apparatus of claim 16, wherein the PIC die comprises a first waveguide, a modulator coupled to the first waveguide, a second waveguide, and a photodetector coupled to the second waveguide.
